(19) United States
(12) Patent Application Publication
(10) Pub. No.: US 2026/0359532 A1
(43) Pub. Date: Nov. 12, 2026

(54) SYSTEM AND METHOD FOR GENERATING A SIMULATION-READY SPARSE THREE-DIMENSIONAL SURFACE OF A CHIP LAYOUT

(71) Applicant: SAMSUNG ELECTRONICS CO., LTD., Suwon-si (KR)

(72) Inventors: Gaurav KUMAR, Bengaluru (IN); Shashank Shrikant AGASHE, Bengaluru (IN); Kumar BALAKRISHNA, Bengaluru (IN); Sameer SHARMA, Bengaluru (IN); Siddhrath JANDIAL, Bengaluru (IN)

(73) Assignee: SAMSUNG ELECTRONICS CO., LTD., Suwon-si (KR)

(21) Appl. No.: 19/666,821

(22) Filed: May 4, 2026

(30) Foreign Application Priority Data
May 2, 2025 (IN) 202541042851
May 1, 2026 (IN) 202541042851

(51) Int. Cl. G06F 30/31; G06T 17/10; G06T 17/20

(52) U.S. Cl. CPC G06F 30/31; G06T 17/10; G06T 17/205

(57) ABSTRACT

An apparatus and method for generating a simulation-ready sparse three-dimensional (3D) surface of a chip layout is described. The method includes receiving parameterized 3D model comprising plurality of elemental 3D blocks, etching information The etching information identifies an etching cycle in the parameterized 3D model that represents the chip layout. The method includes generating the simulation-ready sparse 3D surface comprising etch pockets based on the etching information. The etch pockets are configured to interrupt the etching cycle. The method includes assigning a rendering order to each of the plurality of elemental 3D blocks for reducing the etching cycle based on a manufacturing sequence. An elemental 3D block corresponding to upper manufacturing sequence is assigned higher rendering order than elemental 3D block corresponding to lower manufacturing sequence. The method includes generating the simulation-ready sparse 3D surface based on the plurality of etch pockets and the rendering order.

### CROSS-REFERENCE TO RELATED APPLICATIONS

This application is based on and claims priority under 35 U.S.C. § 119 to Indian Patent Application number 202541042851 filed on May 2, 2025 and Indian Patent Application number 202541042851 filed on May 1, 2026 in the Office of the Controller General of Patents, Designs and Trade Marks, the disclosures of which are incorporated herein in their entireties by reference.

### BACKGROUND

The present application relates to the field of semiconductor chip simulation software and platforms, and more particularly relates to a method and a system for method and system for generating a simulation-ready sparse three-dimensional (3D) surface of a chip layout.

Semiconductor fabrication utilizes process and inspection steps that rely on simulations to optimize equipment and enhance yield using three-dimensional (3D) models of chip layouts. 3D surfaces for chip layouts are created primarily for theoretical verification of fabrication processes in semiconductor fabrication facilities (FABs). Theoretical data generated from these 3D surfaces are validated against measured output, enabling various tasks such as equipment calibration and root cause analysis.

In semiconductor chip simulation platforms, a chip layout is commonly represented as a 3D model composed of multiple elemental geometric units. These elemental units, referred to herein as 3D blocks B, constitute the fundamental building blocks of the parameterized 3D model used to represent fabrication recipes and structural features of a semiconductor device. Each block B corresponds to a primitive or compound geometric entity that describes a material region formed during a deposition, etching, or patterning step in the manufacturing sequence. The blocks B are preferably expressed in analytical or functional form, such as parameterized mathematical formulations including superquadric-based representations. The superquadric-based representations enable compact description, scalability, and deterministic reconstruction of geometry. A complete chip layout is therefore defined as an ordered list or sequence of such blocks B, where the order of B reflects the process flow and manufacturing sequence used during fabrication.

FIG. 1a illustrates an overview of 3D elemental block B, according to the prior art.

Superquadrics use a compact set of parameters to define flexible and precise 3D shapes for chip layout modeling. The core configuration parameters (a, b, c) define the size of the shape along the three spatial axes, while the shape parameters (n₁, n₂) control the curvature, allowing the geometry to smoothly vary from rounded to sharp-edged forms. The position parameters (x, y, z) specify the location of the 3D block within the overall chip layout. Additional periodic repeat parameters (Rₓ, R_{y}, R_{z}) enable efficient representation of regularly repeating structures, and the material parameter (M) associates each block with specific material properties required for accurate physical and simulation behavior:

$${( {\vert \frac{x}{a} \vert}^{{n}_{2}} + {\vert \frac{y}{b} \vert}^{{n}_{2}} )}^{{n}_{1 / {n}_{2}}} + {\vert \frac{z}{c} \vert}^{{n}_{1}} - 1 = 0.$$

FIG. 1b and FIG. 1c illustrate B conversion to sparse format or dense format, respectively, according to the prior art.

In the semiconductor industry, 3D surfaces are categorized into two primary types: dense 3D surfaces (voxel-based) and sparse 3D surfaces (poly mesh-based). Static models are used for simulation but cannot fine-tune equipment parameters, while parameterized models are trainable, expressed as functions, and optimized for optimal equipment settings using critical dimensions (CD). Parameterized models are derived from ideal chip layouts using domain expertise and are converted into static models for simulation use via 3D surface creation algorithms.

FIG. 1d illustrates parameterized 3D model samples represented using a list of block B, according to the prior art.

Constructive solid geometry (CSG) operations in sparse 3D surface generation suffer from numerical precision issues, resulting in artifact addition or missing polygon problems.

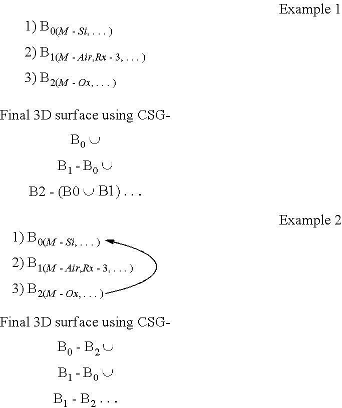

The arrow in example 2 from lower sequence block B to upper block B represents the etching operations.

FIG. 2a illustrates issues in voxel-based (dense 3D format) surface, according to the prior art.

Voxel-based surfaces suffer from approximation errors at boundaries where the discrete voxel grid cannot accurately represent curved or angled surfaces. Additionally, voxel data size can easily grow to multiple gigabytes (GBs) for a mid-size chip layout, requiring substantial computational resources and processing time. The large data footprint makes voxel-based approaches impractical for real-time simulation and iterative optimization processes.

FIG. 2b illustrates issues with a poly-mesh (sparse 3D format) surface, according to the prior art.

The defects related to artifact addition or missing polygon problems cause significant errors in simulation results, such as simulated spectrum errors in optical metrology applications. Furthermore, the structure of parameterized 3D models has inherent etching cycles due to reverse-etching, wherein upper sequence blocks inherently etch lower sequence blocks, making it extremely difficult to avoid numerical precision errors during CSG operations.

The existing approaches rely on modeling and animating two-dimensional (2D) and three-dimensional (3D) deformable objects in physically based simulation methods. However, in such methods, chip layouts are not deformable, and the simulation requirements in semiconductor fabrication, such as rigorous coupled-wave analysis (RCWA)-based electromagnetic simulation used during inspection, differ fundamentally from deformable object animation.

Another existing method employs low-poly mesh generation for 3D models, where the input is a 3D mesh that is transformed into a low-poly mesh. In contrast, the present invention uses a parameterized 3D recipe for chip layouts to create 3D surfaces, addressing the unique requirements of semiconductor fabrication simulation.

Therefore, there is a need for enhanced techniques to address the above-mentioned deficiencies.

### SUMMARY

This summary is provided to introduce a selection of concepts, in a simplified format, that are further described in the detailed description of the disclosure. This summary is neither intended to identify key nor essential inventive concepts of the disclosure, nor is it intended to determine the scope of the disclosure.

According to an embodiment, a method for generating a simulation-ready sparse three-dimensional (3D) surface of a chip layout is provided. The method may include receiving a parameterized 3D model comprising a plurality of elemental 3D blocks and etching information. The etching information identifies an etching cycle in the parameterized 3D model that represents the chip layout. Further, the method includes generating the sparse 3D surface comprising a plurality of etch pockets based on the etching information, wherein the etch pockets are configured to interrupt the etching cycle. Furthermore, the method includes assigning a rendering order to each of the plurality of elemental 3D blocks for reducing the etching cycle based on a manufacturing sequence. An elemental 3D block corresponding to an upper manufacturing sequence is assigned a higher rendering order than an elemental 3D block corresponding to a lower manufacturing sequence. Additionally, the method includes generating the simulation-ready sparse 3D surface based on the plurality of etch pockets and the rendering order.

According to an embodiment, an apparatus for creating an optimized and error-free sparse three-dimensional (3D) surface of a chip layout for semiconductor simulation is provided. The apparatus may include a memory and at least one processor operatively coupled to the memory. The at least one processor is configured to receive a parameterized 3D model comprising a plurality of elemental 3D blocks, etching information. The etching information identifies an etching cycle in the parameterized 3D model that represents the chip layout. Further, the at least one processor is configured to generate the sparse 3D surface comprising a plurality of etch pockets based on the etching information. The etch pockets are configured to interrupt the etching cycle. Furthermore, the at least one processor is configured to assign a rendering order to each of the plurality of elemental 3D blocks for reducing the etching cycle based on a manufacturing sequence. An elemental 3D block corresponding to an upper manufacturing sequence is assigned a higher rendering order than an elemental 3D block corresponding to a lower manufacturing sequence. Additionally, the at least one processor is configured to generate the simulation-ready sparse 3D surface based on the plurality of etch pockets and the rendering order.

To further clarify the advantages and features of the present disclosure, a more particular description of the disclosure will be rendered by reference to specific embodiments thereof, which are illustrated in the appended drawings. It is appreciated that these drawings depict only typical embodiments of the disclosure and are therefore not to be considered limiting of its scope. The disclosure will be described and explained with additional specificity and detail in the accompanying drawings.

### BRIEF DESCRIPTION OF DRAWINGS

Features, aspects, and advantages of embodiments of the disclosure will be described below with reference to the accompanying drawings, in which reference numerals denote like elements, and wherein:

FIG. 1a illustrates an overview of 3D elemental block B, according to the prior art;

FIG. 1b and FIG. 1c illustrate B conversion to sparse format or dense format, respectively, according to the prior art;

FIG. 1d illustrates parameterized 3D model samples represented using a list of block B, according to the prior art;

FIG. 2a illustrate issues in voxel-based (dense 3D format) surface, according to the prior art;

FIG. 2b illustrates issues with a poly-mesh (sparse 3D format) surface, according to the prior art;

FIG. 3 illustrates an environment for the implementation of a system for creating an optimized and error-free sparse three-dimensional (3D) surface of a chip layout for semiconductor simulation, in accordance with one or more embodiments of the disclosure;

FIG. 4 illustrates the system for creating the optimized and error-free sparse 3D surface of the chip layout for the semiconductor simulation, in accordance with one or more embodiments of the disclosure;

FIG. 5 illustrates a process flow for generating an error-free 3D surface, in accordance with one or more embodiments of the disclosure;

FIG. 6a illustrates an example of the canonical 3D model, in accordance with one or more embodiments of the disclosure;

FIG. 6b illustrates an example of a simulation-ready sparse 3D surface model, in accordance with one or more embodiments of the disclosure;

FIG. 7a illustrates an example of the generation of a display-ready 3D surface model, in accordance with one or more embodiments of the disclosure;

FIG. 7b illustrates an example of the generation of artifact-free 3D surface, in accordance with one or more embodiments of the disclosure;

FIG. 8a illustrates an example of a process flow for the generation of a 3D voxel representation, in accordance with one or more embodiments of the disclosure;

FIG. 8b illustrates an example of a process flow for the generation of a confidence score, in accordance with one or more embodiments of the disclosure; and

FIG. 9 illustrates a process flow of a method for creating the optimized and error-free sparse 3D surface of the chip layout for the semiconductor simulation, in accordance with one or more embodiments of the disclosure.

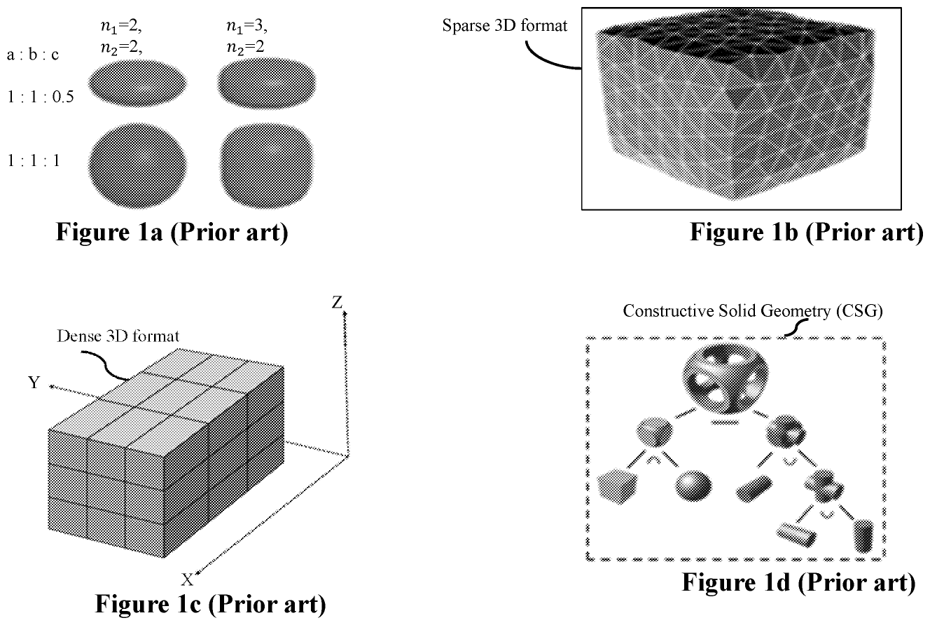

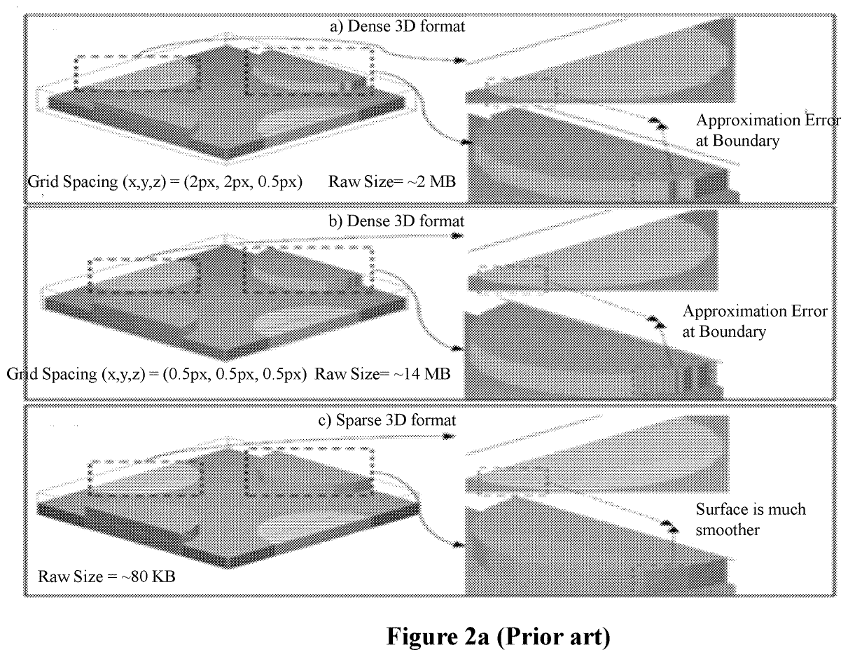

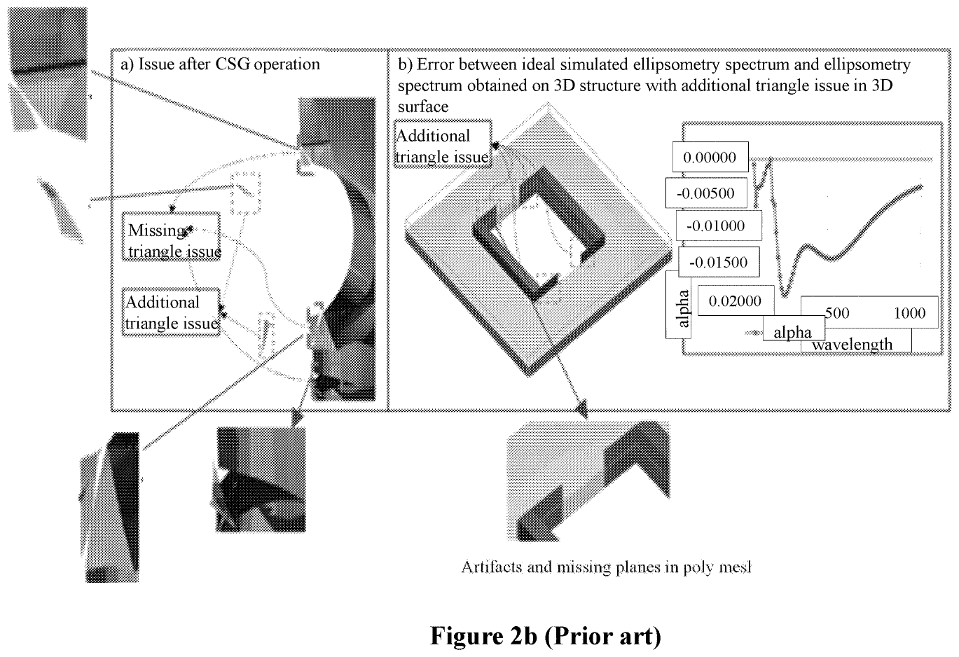

Further, skilled artisans will appreciate that elements in the drawings are illustrated for simplicity and may not have necessarily been drawn to scale. For example, the flow charts illustrate the method in terms of the most prominent steps involved to help improve understanding of aspects of the present invention. Furthermore, in terms of the construction of the device, one or more components of the device may have been represented in the drawings by conventional symbols, and the drawings may show only those specific details that are pertinent to understanding the embodiments of the present invention so as not to obscure the drawings with details that will be readily apparent to those of ordinary skill in the art having the benefit of the description herein.

### DETAILED DESCRIPTION

For the purpose of promoting an understanding of the principles of the invention, reference will now be made to the various embodiments, and specific language will be used to describe the same. It will nevertheless be understood that no limitation of the scope of the invention is thereby intended, such alterations and further modifications in the illustrated system, and such further applications of the principles of the invention as illustrated therein, being contemplated as would normally occur to one skilled in the art to which the invention relates.

It will be understood by those skilled in the art that the foregoing general description and the following detailed description are explanatory of the invention and are not intended to be restrictive thereof.

Reference throughout this specification to “an aspect,” “another aspect,” or similar language means that a particular feature, structure, or characteristic described in connection with the embodiment is included in at least one embodiment of the present invention. Thus, appearances of the phrase “in an embodiment”, “in another embodiment”, and similar language throughout this specification may, but do not necessarily, all refer to the same embodiment.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components preceded by “comprises . . . a” does not, without more constraints, preclude the existence of other devices or other sub-systems or other elements or other structures or other components or additional devices or additional sub-systems or additional elements or additional structures or additional components.

The present disclosure relates to techniques for generating a simulation-ready sparse three-dimensional (3D) surface of a chip layout. In particular, the present disclosure provides a method and a system that creates a plurality of etch pockets to break etching cycles increasingly present in parameterized 3D model recipes that represent the chip layout. An actual chip fabrication generally follows a unidirectional manufacturing sequence and does not involve etching cycles, whereas the etching cycles may not be a physical fabrication phenomenon. The etching cycles may be introduced only when the manufacturing sequence is converted into the parameterized 3D model, where mathematical and geometric constraints require upper and lower model blocks to perform reverse-etching operations on each other. By generating the plurality of etch pockets through CSG intersection operations, the algorithm eliminates reverse-etching problems that cause numerical precision errors in conventional approaches. The disclosed method and the system further introduce a rendering order approach between opaque materials to minimize CSG operations. By assigning rendering orders based on manufacturing sequence. The manufacturing sequence may be referred to as a sequence of block as per input parameterized 3D modelling recipe. Further, the manufacturing sequence may be different with actual chip fabrication manufacturing sequence. An elemental 3D block corresponding to an upper manufacturing sequence is assigned a higher rendering order than an elemental 3D block corresponding to a lower manufacturing sequence, the invention significantly reduces the number of CSG subtraction operations required while maintaining an accurate representation of etching operations. Furthermore, the disclosed method and the system provide an auto-validation technique that generates confidence scores indicative of the correctness of the simulation-ready 3D surface. The algorithm generates a reference voxel from the parameterized 3D model. The parameterized 3D model is compared with a voxel-based representation of the sparse 3D surface to detect artifacts and quantify surface accuracy. Furthermore, the disclosed method and the system achieve approximately 384× speedup compared to legacy techniques and produces an average confidence score of 93.472% for generated 3D surfaces, demonstrating significant improvements in both performance and accuracy.

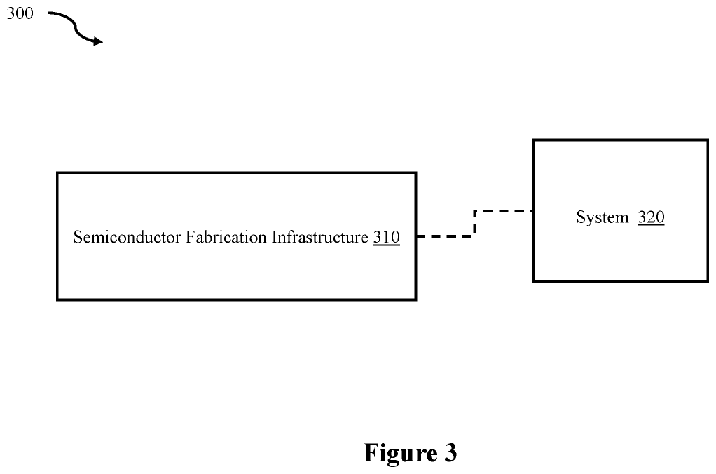

FIG. 3 illustrates an environment 300 for the implementation of a system 320 for creating an optimized and error-free sparse three-dimensional (3D) surface of a chip layout for semiconductor simulation, in accordance with one or more embodiments of the disclosure.

In an exemplary embodiment, the environment 300 may find application in semiconductor fabrication facilities where metrology and inspection equipment may be calibrated using accurate three-dimensional representations of chip layouts. As referred to in FIG. 3, the system 320 may be integrated with a semiconductor fabrication infrastructure 310. The semiconductor fabrication infrastructure 310 may include manufactured chip production lines, one or more metrology and inspection equipment that may perform quality checks and produce measurement output. Further, the semiconductor fabrication infrastructure 310 may include simulation platforms that may perform rigorous coupled-wave analysis-based electromagnetic simulation. Additionally, the semiconductor fabrication infrastructure 310 may include artificial intelligence and machine learning fitting systems that may optimize parameterized 3D models through back-propagation of fitting errors to change three-dimensional model parameters, including critical dimensions.

In an implementation, engineers may create a parameterized three-dimensional model based on the ideal chip layout design using the system 320. The parameterized 3D model may include a plurality of elemental 3D blocks with associated etching information. In a non-limiting example, etching information may refer to process-related data associated with the parameterized 3D model, including etch maps, etch depth parameters, material removal rules, and identification of etching cycles between elemental 3D blocks. In an implementation, an etching cycle may refer to a cyclic dependency in which one or more elemental 3D blocks perform etching operations on lower-sequence blocks. The subsequent blocks in the manufacturing sequence reverse-etch previously formed material regions.

The parameterized 3D model may be fitted and further used to calibrate process equipment such as, but not limited to, etching equipment, deposition lithography equipment, the metrology and inspection equipment, and the like, of the fabrication infrastructure 310. The system 320 may perform 3D surface creation to transform the parameterized 3D model into a static 3D model that may be represented in either voxel format or triangulation poly mesh format. The static 3D model may serve as input to the simulation. The simulation may produce simulation output through theoretical analysis. The system 320 may implement a feedback loop where the measurement output may be fed into a fitting process utilizing artificial intelligence and machine learning techniques. The system 320 may further perform back-propagation of fitting error to change three-dimensional model parameters, including critical dimensions, connecting back to the parameterized three-dimensional model for iterative refinement. The detailed functioning of the system 320 is explained in the forthcoming paragraphs.

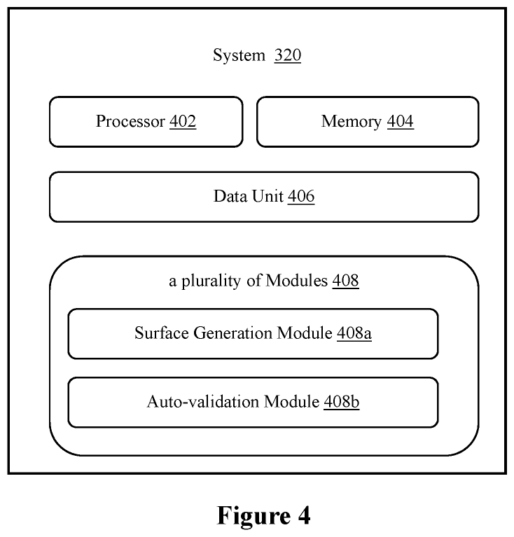

FIG. 4 illustrates the system 320 for creating the optimized and error-free sparse 3D surface of the chip layout for the semiconductor simulation, in accordance with one or more embodiments of the disclosure.

In an embodiment, the system 320 may include at least one processor 402, a memory 404, a data unit 406, and a plurality of modules 408. In an implementation, the system 320 may be implemented in the electronic device 104. For example, the system 320 may be a computer-implemented system. In another implementation, the system 320 may be implemented on the server or the cloud platform.

In an embodiment, the at least one processor 402 may be in communication with the memory 404. The at least one processor 402 may be configured to execute instructions stored in the memory 404 and to perform various processes for creating the optimized and error-free sparse 3D surface of the chip layout for the semiconductor simulation, as discussed throughout the disclosure. The at least one processor 402 may be configured to initiate or stop one or more routines or a process based on the creation of the optimized and error-free sparse 3D surface of the chip layout for the semiconductor simulation. The at least one processor 402 may be a single processing unit or several units, all of which could include multiple computing units. The at least one processor 402 may be implemented as one or more microprocessors, microcomputers, microcontrollers, digital signal processors (DSPs), central processing units (CPUs), an application processor (AP), or like, a graphics-only processing unit such as a graphics processing unit (GPU), a visual processing unit (VPU), and/or an Artificial intelligence (AI) dedicated processor such as a neural processing unit (NPU), state machines, logic circuitries, and/or any devices that manipulate signals based on operational instructions. Among other capabilities, the at least one processor 402 may be configured to fetch and execute computer-readable instructions and data stored in the memory 404.

In an embodiment, the memory 404 stores instructions to be executed by the at least one processor 402 for creating the optimized and error-free sparse 3D surface of the chip layout for the semiconductor simulation, as discussed throughout the disclosure. The memory 404 may include non-volatile storage elements. Examples of such non-volatile storage elements may include magnetic hard discs, optical discs, floppy discs, flash memories, or forms of electrically programmable memories (EPROM) or electrically erasable and programmable (EEPROM) memories. In addition, the memory 404 may, in some examples, be considered a non-transitory storage medium. The term “non-transitory” may indicate that the storage medium is not embodied in a carrier wave or a propagated signal. However, the term “non-transitory” should not be interpreted as the memory 404 is non-movable. In some examples, the memory 404 may be configured to store larger amounts of information. In certain examples, a non-transitory storage medium may store data that can, over time, change (e.g., in Random Access Memory (RAM) or cache). The memory 404 may be an internal storage unit, or an external storage unit of the system 320, a cloud storage, or any other type of external storage.

In an embodiment, the data unit 406, amongst other things, may include routines, programs, objects, components, data structures, and the like, which may help in performing particular tasks or implementing data types. The data unit 406 may be implemented as signal processor(s), state machine(s), logic circuitries, or other devices/components that manipulate signals based on operational instructions. Further, the data unit 406 may be implemented in hardware, instructions executed by a processing unit, or by a combination thereof.

In an embodiment, the plurality of modules 408 may include routines, programs, objects, components, data structures, and the like, which perform tasks or implement data types. The plurality of modules 408 may also be implemented as signal processor(s), state machine(s), logic circuitries, and/or any other device or components. Further, the plurality of modules 408 can be implemented in hardware, instructions executed by a processing unit, or by a combination thereof. The at least one processor 402 may be configured to execute machine-readable instructions (software), via the plurality of modules 408, that may perform the working of the system 320 within the scope of the present disclosure as described in forthcoming paragraphs.

In an embodiment, the plurality of modules 208 may include a surface generation module 408a and an auto-validation module 208b. The detailed functioning of the surface generation module 408a and the auto-validation module 208b is explained in the forthcoming paragraphs.

In an embodiment, the at least one processor 402 may be configured to receive a parameterized 3D model comprising a plurality of elemental 3D blocks, etching information. The etching information may identify an etching cycle in the parameterized 3D model that represents the chip layout.

In an embodiment, the at least one processor 402 may be configured to generate the sparse 3D surface comprising a plurality of etch pockets. The generation of the sparse 3D surface may be based on the etching information. The plurality of etch pockets may be configured to interrupt the etching cycle. In implementation, the plurality of etch pockets may modify the parameterized 3D model to eliminate at least a subset of etching operations contributing to the etching cycle, which may reduce the etching cycle.

In an embodiment, the at least one processor 402 may be configured to assign a rendering order to each of the plurality of elemental 3D blocks for reducing the etching cycle based on a manufacturing sequence. The manufacturing sequence may be a predefined and available at the time of initiating 3D modelling of the chip layout. The manufacturing sequence may be executed either virtually through process simulation or physically using manufacturing equipment. An elemental 3D block corresponding to an upper manufacturing sequence may be assigned a higher rendering order than an elemental 3D block corresponding to a lower manufacturing sequence. In an implementation, the at least one processor 402 may be configured to assign the rendering order to each of the plurality of elemental 3D blocks, having an opacity characteristic, based on a manufacturing sequence for minimizing 3D surface artifacts for creating the simulation-ready sparse 3D surface of the chip layout. Each elemental 3D block may be associated with the opacity characteristic, indicating whether the block represents an opaque or non-opaque material region for constructive solid geometry (CSG) operations. The manufacturing sequence may be a predefined sequence of fabrication steps that may be known at the time of initiating 3D modeling of the chip layout and may be executed virtually via process simulation or physically using fabrication equipment.

In an embodiment, the at least one processor 402 may be configured to generate the simulation-ready sparse 3D surface based on the plurality of etch pockets and the rendering order.

In an embodiment, the at least one processor 402 may be configured to determine a confidence score indicative of the correctness of the simulation-ready 3D surface. Further, the at least one processor 402 may be configured to validate the simulation-ready sparse 3D surface based on the confidence score.

In an implementation, the at least one processor 402 may be configured to receive one or more grid spacing parameters defining a 3D grid based on the parameterized 3D model, wherein the one or more grid spacing parameters comprise a plurality of values defining spacing in x, y, and z directions of the 3D grid. Further, the at least one processor 402 may be configured to generate a reference voxel-based representation from the parameterized 3D model by performing line-based queries to determine material properties at each grid point of the 3D grid. Furthermore, the at least one processor 402 may be configured to generate a comparison voxel-based representation from the simulation-ready 3D surface. Additionally, the at least one processor 402 may be configured to compare the reference voxel-based representation with the comparison voxel-based representation at each grid point to identify material discrepancies. Further, the confidence score may be determined based on the comparison. In an implementation, the at least one processor 402 may be configured to determine the confidence score based on averaging results of the comparison of the reference voxel-based representation with the comparison voxel representation across 3D grid points.

In an embodiment, the correctness of the simulation-ready sparse 3D surface may be evaluated using a voxel-based reference representation. In a non-limiting example, voxel-based surfaces may be employed in the semiconductor simulations. The voxel-based reference surface may be compared with the generated poly-mesh sparse 3D surface to determine the confidence score. The reference voxel-based representations may not exactly match poly-mesh renderings due to inherent approximation errors at material boundaries. However, boundary regions may constitute less than five percent of the total voxel volume. In a non-limiting example, the confidence score greater than 95 percent indicates an almost error-free simulation-ready 3D surface suitable for simulation. A confidence score between 80 percent and 95 percent indicates minor discrepancies in the simulation-ready 3D surface that have a limited impact on simulation accuracy, while a confidence score below 80 percent indicates major inconsistencies, suggesting that the generated 3D surface may require further refinement before being used for simulation purposes.

In an embodiment, the at least one processor 402 may be configured to generate a display-ready 3D surface by performing CSG operations by assigning the rendering order at least between the simulation-ready 3D surface and an air pocket. The CSG operations create the 3D surface by combining basic primitive shapes associated with the parameterized 3D model. In an implementation, the air pocket may be referred to as a transparent area in a 3D space that may be filled by a transparent material such as, but not limited to, gases used during the chip fabrication such as etching gases, inert gases or air.

In an embodiment, the at least one processor 402 may be configured to remove additional surface triangles from the display-ready 3D surface by applying positional shifting of surface vertices by a delta value in x, y, and z directions within a predefined range.

In an embodiment, the at least one processor 402 may be configured to apply a post-processing mesh cleaning operation to the simulation-ready 3D surface, wherein the post-processing mesh cleaning operation is for minimizing 3D surface artifacts.

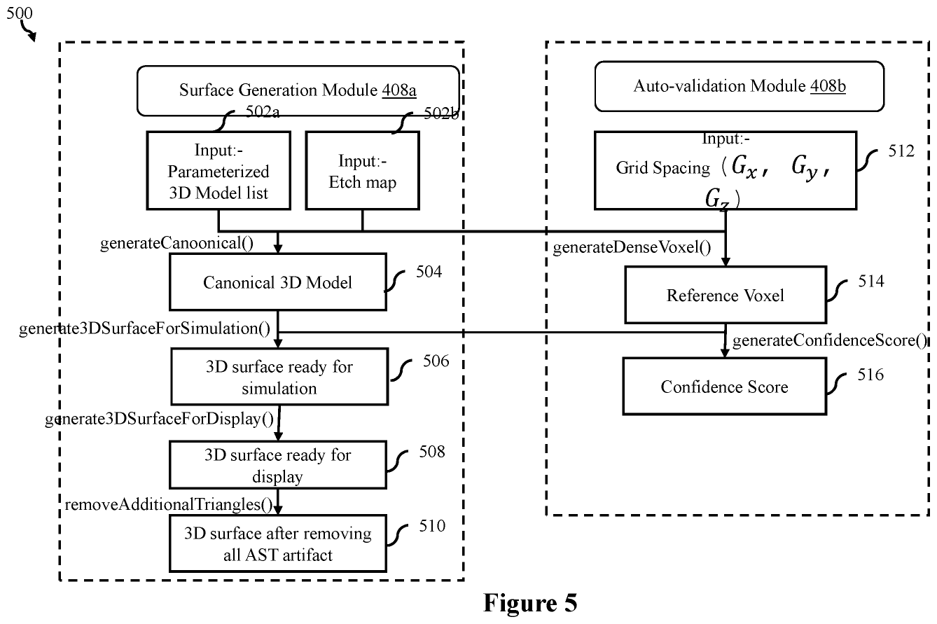

FIG. 5 illustrates a process flow 500 for generating an error-free 3D surface, in accordance with one or more embodiments of the disclosure.

In an embodiment, as referred to in FIG. 5, the plurality of modules, including the surface generation module 408a and the auto-validation module 208b, may be configured for performing automated generation, validation, and preparation of the 3D surfaces derived from parameterized 3D models. The surface generation module 408a may be configured to transform input geometric representations into canonical, defect-free 3D surfaces suitable for simulation and visualization, while automatically detecting and correcting surface artifacts.

In an embodiment, the process 500 may generate the optimized and error-free 3D surface of the semiconductor chip layout for simulation and visualization purposes. The process 500 may be receiving the parameterized 3D chip layout model corresponding to a fabrication recipe. The process 500 may simplify the parameterized 3D chip layout model into the canonical representation by identifying and breaking cyclic etching dependencies inherently present in the layout. Etching operations may be further optimized by assigning a deterministic rendering order to opaque material blocks, such that an upper sequence block may be rendered with a higher priority than a lower sequence block. The lower sequence block may correspond to the lower manufacturing sequence. Thus, the optimized etching operations may minimize the number of CSG subtraction operations required during surface generation. The processing of the CSG operations may be constrained to generate a manifold polygonal mesh to prevent topological inconsistencies, such as missing polygons or non-manifold edges. Following surface generation, a post-processing mesh cleaning technique may be applied to remove spurious artifacts, including isolated faces and numerical precision-induced defects. The process 500 may further include an auto-validation mechanism wherein the generated sparse 3D surface may be converted into a first voxel-based dense reference surface (Surface A) using a low-precision voxel grid sampling process. Further, process 500 may generate a second voxel-based surface (Surface B) that may be independently derived directly from the parameterized 3D chip layout model. The two voxel representations may be compared on a per-voxel basis to identify discrepancies indicative of surface artifacts, and the confidence score may be computed based on the degree of correspondence between the Surface A and the Surface B. The confidence score may serve as a quantitative measure of the correctness of the generated sparse 3D surface and may be used to qualify the surface for subsequent simulation, analysis, or visualization workflows.

At step 502a and 502b, the surface generation module 408a may receive a parameterized 3D model list and an associated etch map as inputs.

Subsequently, at step 512, the surface generation module 408a may also receive defined grid spacing parameters (Gx, Gy, Gz) from the auto-validation module 208b, as input. The parameterized 3D model list may represent one or more geometric structures defined using the CSG operations or similar mathematical representations. The etch map may specify process-related information governing material removal or modification. The grid spacing parameters may define the spatial resolution at which the 3D models may be discretized and processed.

The surface generation module 408a may be configured to process the inputs. The surface generation module 408a may be responsible for constructing intermediate and final geometric representations.

At step 504, the surface generation module 408a may implement a conversion to convert the parameterized 3D models into the canonical representation, such as a canonical 3D model. The conversion may normalize geometric definitions into a consistent representation suitable for downstream voxelization and surface extraction. In a non-limiting example, the surface generation module 408a may implement a generateCanonical( ) function to convert the parameterized 3D models into the canonical 3D model. In an advantageous aspect, the canonicalization step may ensure uniform handling of geometric primitives and eliminate representation inconsistencies originating from different modeling sources.

Subsequently, at step 514, the auto-validation module 208b may generate a dense 3D voxel representation based on the canonical 3D model using the specified grid spacing. The 3D voxel representation may act as the reference voxel-based representation. The reference voxel-based representation may be used as a baseline element for localized error analysis and confidence computation. In a non-limiting example, the auto-validation module 208b may implement a generateDense Voxel( ) function that operates on the canonical 3D model using the specified grid spacing to generate a dense 3D voxel representation. The voxelized form may discretize the geometry into volumetric elements and serve as a robust intermediate structure for reliable surface generation, mitigating ambiguities introduced by complex or intersecting geometry.

At step 506, the surface generation module 408a may extract the 3D surface ready for simulation from the dense voxel representation. In a non-limiting example, the surface generation module 408a may implement a generate3DSurfaceForSimulation( ) function to extract the 3D surface ready for simulation. The 3D surface may be optimized for numerical analysis tools, such as ellipsometry or electromagnetic simulators, where geometric correctness directly impacts simulation accuracy.

At step 508, the surface generation module 408a may generate a 3D surface ready for display. The generated 3D surface, ready for display, may be optimized for visualization, rendering efficiency, or user inspection without altering the underlying geometric fidelity required for simulations. In a non-limiting example, the surface generation module 408a may implement a generate3DSurfaceForDisplay( ) function for the generation of the 3D surface ready for display.

The output surfaces corresponding to the generated 3D surface, ready for display, may be provided to the auto-validation module 408b.

At step 510, the surface generation module 408a may be configured to detect the surface defects and validation issues resulting from voxelization, Boolean operations, or numerical approximations. In a non-limiting example, the surface generation module 408a may implement a removeAdditionalTriangles( ) function that may identify and eliminate unintended surface artifacts. The unintended surface artifacts may include, but are not limited to, additional triangles, overlapping triangles, missing facets, non-manifold edges, and additional surface triangles (AST) artifacts. In an advantageous aspect, the identification and elimination of the unintended surface artifacts may produce the 3D surface, ensuring topological correctness and structural integrity.

At step 516, the auto-validation module 408b may further compute quality metrics. In a non-limiting example, the auto-validation module 408b may implement a generateConfidenceScore( ) function. The generateConfidenceScore( ) function may evaluate the validated surface against reference criteria, such as voxel consistency, surface continuity, and deviation from the canonical 3D model, and outputs the confidence score indicative of the reliability and readiness of the generated 3D surface.

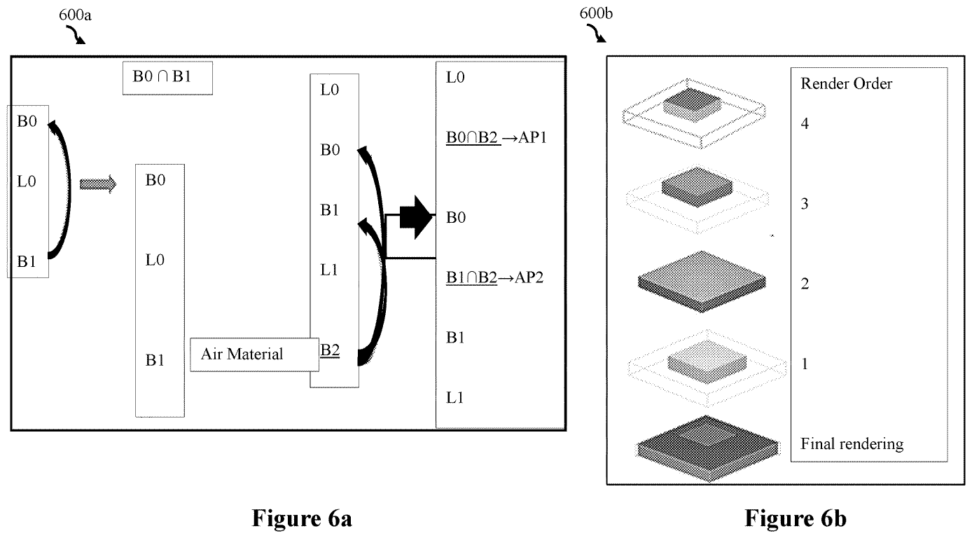

FIG. 6a illustrates an example of the canonical 3D model 600a, in accordance with one or more embodiments of the disclosure.

In an embodiment, the system 320 may be configured to implement the surface generation module 408a and the auto-validation module 208b for generating the canonical 3D model from the parameterized 3D chip layout model and associated etching information. The system 320 may receive the parameterized 3D model as input, describing geometric features of the semiconductor layout along with etch map or process-specific etching data. The parameterized 3D chip layout model may be converted into a sparse 3D representation to reduce memory footprint and improve computational efficiency. Using the sparse 3D representation, a canonical model list may be generated by applying CSG intersection operations. The CSG intersection operations may eliminate all etching-specific Boolean operations from the model. Through the entire process, cyclic or recipe-dependent etch operations are resolved and removed, leaving only the final material geometry. In an advantageous aspect, the resulting output may be the canonical 3D model that may represent the finalized chip structure independent of etching operations and which may be suitable for subsequent simulation, validation, or visualization workflows.

In an embodiment, as referred to in FIG. 6a, B0, B1, L0, and the like may represent elemental three-dimensional (3D) shapes (also referred to as blocks) that are realized using at least one mathematical 3D model. In an implementation, the at least one mathematical 3D model may impose one or more mathematical constraints to define a superquadric shape. In a non-limiting example, B0 may be defined as Superquadric (n1=1, n2=2, a=2, b=2, c=2, Pos=(0,0,0)) and L0 may be defined as Superquadric (n1=2, n2=3, a=10, b=20, c=30, Pos=(10,10,10)), and the like. Further, AP1 may represent an air pocket generated based on constructive solid geometry (CSG) interaction operations between B0 and B2, wherein B2 may represent air or gas material. In another implementation, AP2 may represent an air pocket generated through an intersection between B1 and B2, wherein B2 represents air. In yet another implementation, when B2 represents a non-air material, such as silicon, the CSG interaction operations may generate a material pocket (MP1, MP2) in place of the air pocket (AP1, AP2).

FIG. 6b illustrates an example of a simulation-ready sparse 3D surface model 600b, in accordance with one or more embodiments of the disclosure.

In an embodiment, the system 320 may be configured to implement the surface generation module 408a and the auto-validation module 208b for generating the simulation-ready 3D surface from the canonical 3D model using a controlled rendering sequence. The system 320 may receive the canonical 3D model representing the finalized chip geometry independent of any etching operations. The canonical model may be processed by the surface generation function, which may render constituent geometry blocks in a predefined render order. In one example implementation, the rendering sequence may follow a descending priority order of render levels 4, 3, 2, and 1, followed by a final rendering step that may merge the intermediate results into a unified 3D surface. By enforcing the ordered rendering, higher-priority structural features may be preserved while minimizing geometric conflicts, CSG subtraction artifacts, and numerical inconsistencies. In an advantageous aspect, the simulation-ready 3D surface model may be obtained that may be topologically consistent, free of missing surfaces or surface artifacts, and suitable for use in semiconductor process simulation, analysis, and verification workflows.

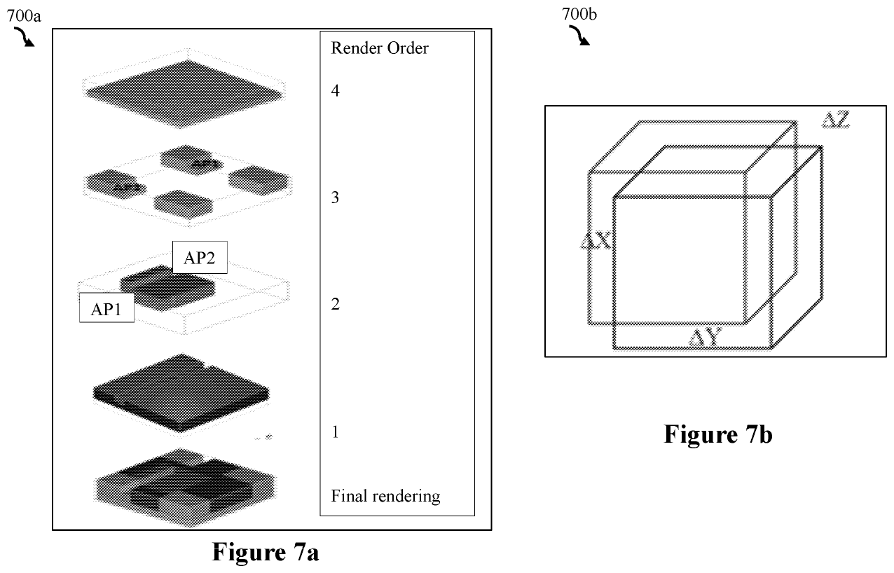

FIG. 7a illustrates an example of the generation of a display-ready 3D surface model 700a, in accordance with one or more embodiments of the disclosure.

In an embodiment, the system 320 may generate the display-ready 3D surface from the simulation-ready sparse 3D surface model 600b. The system 320 may receive, as input, the simulation-ready sparse 3D model 600b that may have been generated with geometric accuracy suitable for process simulation. For display purposes, the simulation-ready surface model 700a may be subjected to the CSG intersection operation with the air pocket that may represent the surrounding empty space. The air pocket intersection may define visible boundaries, remove occluded or non-viewable geometry, and ensure correct visualization of exposed surfaces. The resulting geometry may be optimized for rendering and visualization while preserving the underlying structural fidelity of the simulation-ready surface model 700a. The final output may be the display-ready 3D surface model 700a suitable for graphical visualization, inspection, and presentation, as illustrated in the middle figure of the corresponding drawing.

FIG. 7b illustrates an example of the generation of artifact-free 3D surface 700b, in accordance with one or more embodiments of the disclosure.

In an embodiment, the system 320 may remove the residual surface artifacts from the display-ready 3D surface model 700a to produce the artifact-free 3D surface 700b. The system 320 may receive, as input, a display-ready 3D surface model 700a that may contain additional or redundant surface triangles resulting from numerical precision limits or prior CSG and rendering operations. In an implementation, to eliminate the surface artifacts, a controlled positional perturbation, referred to as a ΔPt (delta-point) shift, may be applied to the model geometry along the x, y, and z axes. The ΔPt shift may be performed within a bounded range of −1 to +1 units in each spatial direction, and the surface may be re-evaluated after each shift to identify and remove degenerate, overlapping, or unnecessary surface triangles. The iterative spatial adjustment may enable robust detection of unstable geometric elements that manifest as rendering surface artifacts. Upon completion of the ΔPt shift-based filtering process. Thus, the resulting output may be a clean, artifact-free 3D surface that may be topologically consistent and suitable for high-quality visualization, inspection, or downstream simulation and analysis.

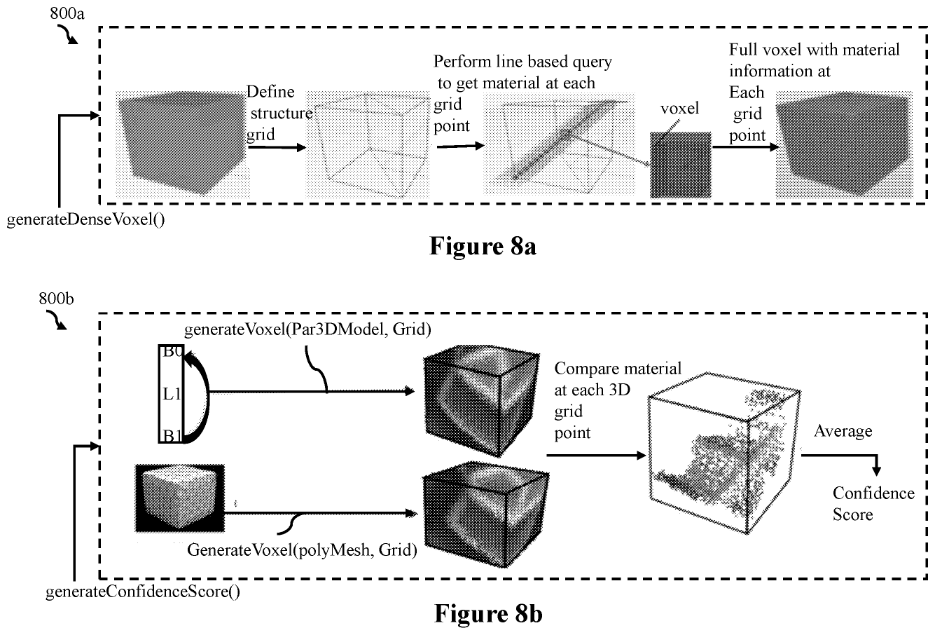

FIG. 8a illustrates an example of a process flow 800a for the generation of the 3D voxel representation, in accordance with one or more embodiments of the disclosure.

In an embodiment, the system 320 may generate the dense voxel-based 3D voxel representation using the generateDense Voxel( ) function. The system 320 may receive, as input, the parameterized 3D model of the chip layout along with associated etching information. A 3D voxel grid structure may first be defined over the three spatial axes encompassing the chip geometry. Further, the grid resolution may be selected based on validation requirements. For each grid point within the voxel structure, a line-based material query may be performed against the parameterized 3D model and etching information to determine the presence and type of material at that location. The results of the line-based queries may be aggregated to populate the voxel grid with material state information at each grid point. In an advantageous aspect, a fully dense voxel representation of the chip structure may be constructed. A voxel array may be output that may serve as the reference voxel-based representation, capturing material occupancy information with spatial fidelity, and is subsequently used for validation, artifact detection, or confidence score generation in downstream processing stages.

FIG. 8b illustrates an example of a process flow 800b for the generation of the confidence score, in accordance with one or more embodiments of the disclosure.

In an embodiment, the system 320 may be configured to determine the confidence score that may quantify the correctness of a generated 3D surface using the getConfidenceScore( ) function. The system 320 may receive, as input, the canonical 3D model and the reference voxel-based representation. A voxelization process may be performed on the canonical 3D model by invoking a generate Voxel(Par3DModel, Grid) function, wherein the parameterized 3D model may be sampled over a predefined 3D grid to determine material occupancy at each grid point. In parallel or as an alternative, for a sparse 3D format such as a polygonal mesh, a GenerateVoxel(polyMesh, Grid) function may be applied to produce a corresponding voxel representation using the same grid definition. Material information at each grid point from the generated voxel representation may be compared against the material information from the reference voxel-based representation on a per-grid-point basis to identify matches and mismatches. Based on the comparison, individual correctness values may be computed for each grid point, and an overall confidence score may be obtained by calculating the average of these values across the entire grid. The resulting confidence score may provide a quantitative measure of the fidelity of the canonical or sparse 3D surface relative to the reference voxel-based representation and may be used to validate the suitability of the surface for simulation, visualization, or further processing.

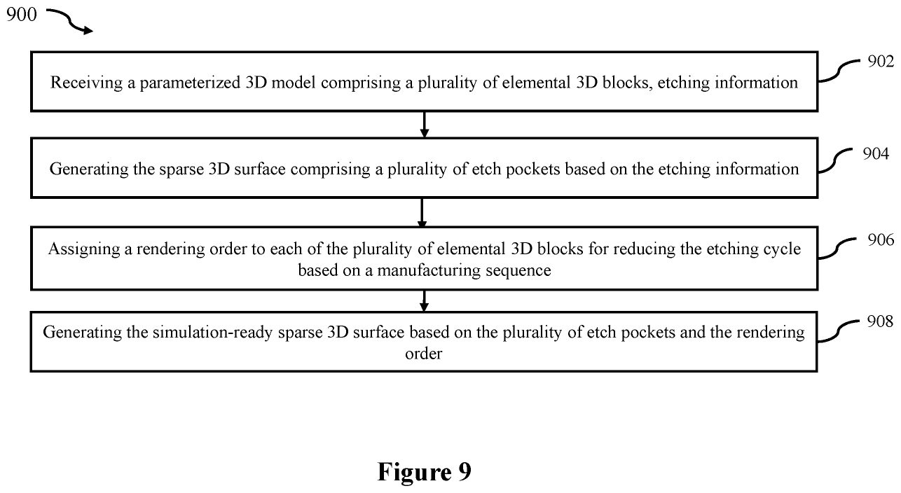

FIG. 9 illustrates a process flow of a method 900 for creating the optimized and error-free sparse 3D surface of the chip layout for the semiconductor simulation, in accordance with one or more embodiments of the disclosure.

The method 900 may be a computer-implemented method executed, for example, by the system 320 and the plurality of modules 408. For the sake of brevity, constructional and operational features of the system 320 that are already explained in the description of FIG. 3, FIG. 4, FIG. 5, FIG. 6a, FIG. 6b, FIG. 7a, FIG. 7b, FIG. 8a, and FIG. 8b are not explained in detail in the description of FIG. 9.

At step 902, the method 900 may include receiving the parameterized 3D model comprising the plurality of elemental 3D blocks, and etching information. The etching information may identify the etching cycle in the parameterized 3D model that may represent the chip layout.

At step 904, the method 900 may include generating the sparse 3D surface comprising the plurality of etch pockets based on the etching information. The plurality of etch pockets may be configured to interrupt the etching cycle.

At step 906, the method 900 may include assigning the rendering order to each of the plurality of elemental 3D blocks for reducing the etching cycle based on the manufacturing sequence. The elemental 3D block corresponding to the upper manufacturing sequence may be assigned a higher rendering order than the elemental 3D block corresponding to the lower manufacturing sequence. In an implementation, the rendering order may be assigned to each of the plurality of elemental 3D blocks, having the opacity characteristic. The assignment may be based on the manufacturing sequence for minimizing 3D surface artifacts for creating the simulation-ready sparse 3D surface of the chip layout.

At step 908, the method 900 may include generating the simulation-ready sparse 3D surface based on the plurality of etch pockets and the rendering order. The plurality of etch pockets may modify the parameterized 3D model to eliminate at least the subset of etching operations contributing to the etching cycle that reduces the etching cycle.

In an embodiment, the method 900 may include determining the confidence score indicative of the correctness of the simulation-ready 3D surface. Further, the method 900 may include validating the simulation-ready sparse 3D surface based on the confidence score. In an implementation, the confidence score may be determined based on receiving one or more grid spacing parameters defining the 3D grid based on the parameterized 3D model. The one or more grid spacing parameters may include a plurality of values defining spacing in the x, y, and z directions of the 3D grid. Further, the confidence score may be determined based on generating the reference voxel-based representation from the parameterized 3D model by performing line-based queries to determine material properties at each grid point of the 3D grid. Furthermore, the confidence score may be determined based on generating the comparison voxel-based representation from the simulation-ready 3D surface. Additionally, the confidence score may be determined based on comparing the reference voxel-based representation with the comparison voxel-based representation at each grid point to identify material discrepancies. Thus, the confidence score may be determined based on the comparison. In another implementation, the confidence score may be determined based on averaging the results of the comparison of the reference voxel-based representation with the comparison voxel representation across 3D grid points.

In an embodiment, the method 900 may include generating the display-ready 3D surface by performing the CSG operations by assigning the rendering order at least between the simulation-ready 3D surface and an air pocket, wherein the CSG operations create the 3D surface by combining basic primitive shapes associated with the parameterized 3D model.

In an embodiment, the method 900 may include removing the additional surface triangles from the display-ready 3D surface. The removal of the additional surface may be based on applying the positional shifting of surface vertices by the delta value in x, y, and z directions within the predefined range.

In an embodiment, the method 900 may include applying the post-processing mesh cleaning operation to the simulation-ready 3D surface, wherein the post-processing mesh cleaning operation may be applied to minimize the 3D surface artifacts.

The present disclosure provides significant technical and practical advantages in the generation and validation of 3D surfaces for semiconductor fabrication simulation. The disclosed system 320 and method 900 substantially improve computational efficiency while maintaining geometric accuracy by converting parameterized chip layouts into optimized sparse 3D surfaces with reduced CSG operations and controlled rendering order. The disclosed system 320 and method 900 implement mesh generation and use post-processing artifact removal techniques to ensure robust, error-free 3D surfaces suitable for high-fidelity simulation and visualization. Additionally, the disclosed system 320 and method 900 implement an auto-validation framework that compares reference voxel-based representations derived from both parameterized models and generated surfaces. Furthermore, the disclosed system 320 and method 900 enable objective correctness assessment through a quantifiable confidence score. Through the disclosed system 320 and method 900, surface generation may be accelerated, which may help in achieving significant speedups over legacy methods. Furthermore, the disclosed system 320 and method 900 can also increase reliability and trust in simulation results, thereby enhancing process analysis, equipment calibration, and yield optimization in semiconductor manufacturing workflows.

While specific language has been used to describe the disclosure, any limitations arising on account of the same are not intended. As would be apparent to a person in the art, various working modifications may be made to the method to implement the inventive concept as taught herein. The drawings and the foregoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein.

What is claimed is:

1. A method for generating a simulation-ready sparse three-dimensional (3D) surface of a chip layout, the method comprising:
receiving a parameterized 3D model comprising a plurality of elemental 3D blocks, etching information, wherein the etching information identifies an etching cycle in the parameterized 3D model that represents the chip layout;
generating the simulation-ready sparse 3D surface comprising a plurality of etch pockets based on the etching information, wherein the plurality of etch pockets are configured to interrupt the etching cycle;
assigning a rendering order to each of the plurality of elemental 3D blocks for reducing the etching cycle based on a manufacturing sequence, wherein an elemental 3D block corresponding to an upper manufacturing sequence is assigned a higher rendering order than an elemental 3D block corresponding to a lower manufacturing sequence; and
generating the simulation-ready sparse 3D surface based on the plurality of etch pockets and the rendering order.

2. The method of claim 1, wherein the plurality of etch pockets modifies the parameterized 3D model to eliminate at least a subset of etching operations contributing to the etching cycle, thereby reducing the etching cycle.

3. The method of claim 1, further comprising:
determining a confidence score indicative of correctness of the simulation-ready 3D surface; and
validating the simulation-ready sparse 3D surface based on the confidence score.

4. The method of claim 3, wherein determining the confidence score comprises:
receiving one or more grid spacing parameters defining a 3D grid based on the parameterized 3D model, wherein the one or more grid spacing parameters comprise a plurality of values defining spacing in x, y, and z directions of the 3D grid;
generating a reference voxel-based representation from the parameterized 3D model based on performing line-based queries to determine material properties at each grid point of the 3D grid;
generating a comparison voxel-based representation from the simulation-ready 3D surface;
comparing the reference voxel-based representation with the comparison voxel-based representation at each grid point to identify material discrepancies; and
determining the confidence score based on the comparison.

5. The method of claim 4, wherein determining the confidence score comprises averaging results of the comparison of the reference voxel-based representation with the comparison voxel representation across 3D grid points.

6. The method of claim 1, further comprising:
generating a display-ready 3D surface based on performing constructive solid geometry (CSG) operations by assigning the rendering order at least between the simulation-ready 3D surface and an air pocket, wherein the CSG operations create the 3D surface by combining basic primitive shapes associated with the parameterized 3D model.

7. The method of claim 6, further comprising:
removing additional surface triangles from the display-ready 3D surface based on applying positional shifting of surface vertices by a delta value in x, y, and z directions within a predefined range.

8. The method of claim 1, further comprising:
applying a post-processing mesh cleaning operation to the simulation-ready 3D surface, wherein the post-processing mesh cleaning operation is applied for minimizing 3D surface artifacts.

9. The method of claim 1, assigning the rendering order to each of the plurality of elemental 3D blocks, having an opacity characteristic, based on a manufacturing sequence for minimizing 3D surface artifacts for creating the simulation-ready sparse 3D surface of the chip layout.

10. An apparatus for creating a simulation-ready sparse three-dimensional (3D) surface of a chip layout for semiconductor simulation, the apparatus comprising:
a memory; and
at least one processor operatively coupled to the memory, wherein the at least one processor is configured to:
receive a parameterized 3D model comprising a plurality of elemental 3D blocks, etching information, wherein the etching information identifies an etching cycle in the parameterized 3D model that represents the chip layout;
generate the simulation-ready sparse 3D surface comprising a plurality of etch pockets based on the etching information, wherein the plurality of etch pockets are configured to interrupt the etching cycle;
assign a rendering order to each of the plurality of elemental 3D blocks for reducing the etching cycle based on a manufacturing sequence, wherein an elemental 3D block corresponding to an upper manufacturing sequence is assigned a higher rendering order than an elemental 3D block corresponding to a lower manufacturing sequence; and
generate the simulation-ready sparse 3D surface based on the plurality of etch pockets and the rendering order.

11. The apparatus of claim 10, wherein the plurality of etch pockets modifies the parameterized 3D model to eliminate at least a subset of etching operations contributing to the etching cycle that reduces the etching cycle.

12. The apparatus of claim 10, wherein the at least one processor is configured to:
determine a confidence score indicative of correctness of the simulation-ready 3D surface; and
validate the simulation-ready sparse 3D surface based on the confidence score.

13. The apparatus of claim 10, wherein to determine the confidence score, the at least one processor is configured to:
receive one or more grid spacing parameters defining a 3D grid based on the parameterized 3D model, wherein the one or more grid spacing parameters comprise a plurality of values defining spacing in x, y, and z directions of the 3D grid;
generate a reference voxel-based representation from the parameterized 3D model based on performing line-based queries to determine material properties at each grid point of the 3D grid;
generate a comparison voxel-based representation from the simulation-ready 3D surface;
compare the reference voxel-based representation with the comparison voxel-based representation at each grid point to identify material discrepancies; and
determine the confidence score based on the comparison.

14. The apparatus of claim 13, wherein the at least one processor is configured to determine the confidence score based on averaging results of the comparison of the reference voxel-based representation with the comparison voxel representation across 3D grid points.

15. The apparatus of claim 10, wherein the at least one processor is configured to:
generate a display-ready 3D surface based on performing constructive solid geometry (CSG) operations by assigning the rendering order at least between the simulation-ready 3D surface and an air pocket, wherein the CSG operations create the 3D surface by combining basic primitive shapes associated with the parameterized 3D model.

16. The apparatus of claim 15, wherein the at least one processor is configured to:
remove additional surface triangles from the display-ready 3D surface based on applying positional shifting of surface vertices by a delta value in x, y, and z directions within a predefined range.

17. The apparatus of claim 10, wherein the at least one processor is configured to:
apply a post-processing mesh cleaning operation to the simulation-ready 3D surface, wherein the post-processing mesh cleaning operation is applied to minimize 3D surface artifacts.

18. The apparatus of claim 10, wherein the at least one processor is configured to assign the rendering order to each of the plurality of elemental 3D blocks, having an opacity characteristic, based on a manufacturing sequence for minimizing 3D surface artifacts for creating the simulation-ready sparse 3D surface of the chip layout.
